(19) United States
(12) Patent Application Publication
(10) Pub. No.: US 2026/0185766 A1
(43) Pub. Date: Jul. 2, 2026

(54) REFRIGERATOR

(71) Applicant: LG Electronics Inc., Seoul (KR)

(72) Inventors: Sunghun LEE, Seoul (KR); Minkyu KIM, Seoul (KR)

(21) Appl. No.: 19/407,534

(22) Filed: Dec. 3, 2025

(30) Foreign Application Priority Data
Dec. 27, 2024 (KR) 10-2024-0199387

(51) Int. Cl. F25D 23/02; F25D 27/00

(52) U.S. Cl. CPC F25D 23/028; F25D 27/00; F25D 2323/021; F25D 2400/36; F25D 2400/40

(57) ABSTRACT

A refrigerator includes a cabinet forming a storage space having a front opening, and a door configured to open and close the storage space. The door includes: a door body having an opening and an insulation material filled around a periphery of the opening; a body panel assembly configured to cover the opening and including a plurality of transparent panels that allow viewing through a rear side of the door; and a panel assembly detachably mounted to the door body. The panel assembly includes a transparent front panel forming a front surface of the door and a transparent display provided on a rear surface of the front panel. The transparent display is disposed to face the body panel assembly.

### CROSS-REFERENCE TO RELATED APPLICATIONS

The present application claims priority under 35 U.S.C. 119 and 35 U.S.C. 365 to Korean Patent Application No. 10-2024-0199387, filed on December 27, 2024), which is hereby incorporated by reference in its entirety.

### BACKGROUND

The present disclosure relates to a refrigerator.

In general, a refrigerator is a household appliance configured to store food items at a low temperature within an internal storage space that is shielded by a refrigerator door. The refrigerator is designed to preserve stored food items in an optimal state by cooling the interior of the storage space using cold air generated through heat exchange with a refrigerant circulating in a refrigeration cycle.

Such refrigerators have been increasingly enlarged and diversified in function in accordance with changes in dietary habits and trends toward product sophistication. Various types of refrigerators equipped with structures and convenience features designed to enhance user convenience have been introduced.

For example, a refrigerator has been developed in which a portion of the refrigerator door has a transparent structure, allowing selective viewing of the interior when an internal light is turned on or off. In addition, refrigerators have been developed in which a display capable of both transparency and image output is provided on the refrigerator door, thereby enabling the display of information necessary for the use of the refrigerator.

However, in such a refrigerator, when a problem occurs in the panel of the refrigerator on which the display is mounted, it is difficult to replace the panel easily.

In addition, during the manufacturing process of the refrigerator door, there is a problem in that the panel or the display may be damaged due to the heat generated by foaming of the insulation material.

### SUMMARY

An embodiment of the present invention is directed to providing a refrigerator in which maintenance of the door is facilitated.

Another embodiment of the present invention is directed to providing a refrigerator with improved assemblability.

Still another embodiment of the present invention is directed to providing a refrigerator in which a printed circuit board (PCB) can be efficiently arranged.

A further embodiment of the present invention is directed to providing a refrigerator that ensures safe use by preventing condensation in a receiving space in which the PCB and the display are accommodated.

In one embodiment, a refrigerator according to an embodiment of the present invention comprises: a cabinet defining a storage space having a front opening; and a door configured to open and close the storage space, wherein the door comprises: a door body having an opening and an insulating material filled around a periphery of the opening; a body panel assembly including a plurality of transparent panels configured to cover the opening and allow viewing of a rear portion of the door; and a panel assembly detachably mounted to the door body, wherein the panel assembly comprises: a transparent front panel forming a front surface of the door; and a transparent display disposed on a rear surface of the front panel, the transparent display being arranged to face the body panel assembly.

The transparent display and a front surface of the body panel assembly may overlap each other in a front-rear direction.

The transparent display may be formed to have a smaller size than the front panel, and a plurality of PCB assemblies may be disposed on a rear surface of the front panel along a periphery of the transparent display.

The front panel may be detachably mounted to the door body in a state in which the transparent display and the PCB assemblies are installed.

The plurality of PCB assemblies may be disposed between the front panel and the transparent display.

The front panel may comprise: a display window overlapping the transparent display and configured to allow viewing therethrough; and a bezel formed to be opaque along a periphery of the display window, wherein the PCB assemblies may be covered by the bezel.

The plurality of PCB assemblies may comprise: a first PCB assembly disposed above the transparent display and connected to a control unit provided in the cabinet to transmit control signals; a third PCB assembly disposed at one of left and right sides of the transparent display and connected to the display; and a second PCB assembly disposed below the transparent display and connected to the third PCB assembly and the first PCB assembly.

A side guide configured to guide a cable connecting the first PCB assembly and the second PCB assembly may be provided on a rear surface of the front panel, and the side guide may be disposed at one of left and right sides of the transparent display, the one side being closer to a hinge device that connects the door and the cabinet.

In another embodiment, a refrigerator according to an embodiment of the present invention comprises: a cabinet forming a storage space having a front opening; and a door configured to open and close the storage space, wherein the door comprises: a door body having an opening and an insulation material filled around a periphery of the opening; a body panel assembly configured to cover the opening, the body panel assembly including a plurality of transparent panels allowing viewing through a rear side of the door; and a panel assembly detachably mounted to the door body, wherein the panel assembly comprises: a transparent front panel forming a front surface of the door; a transparent display provided at a rear side of the front panel; and a PCB assembly disposed between an edge of the front panel and the transparent display, wherein the PCB assembly includes a plurality of PCBs arranged to be stacked in a front–rear direction.

The PCB assembly may comprise: a first PCB disposed laterally of the transparent display and connected to the display; and a second PCB connected to the first PCB, wherein the second PCB may be disposed behind the first PCB in a state where at least a portion of the second PCB overlaps the first PCB.

The PCB assembly may be disposed at one of left and right sides of the front panel, the one side being opposite to a hinge device that connects the door to the cabinet.

The PCB assembly may further comprise: a first case fixed to the front panel, the first PCB being mounted in the first case; and a second case disposed behind the first case, the second PCB being mounted in the second case, wherein the second case may be coupled to the first case in a front–rear direction.

An opaque bezel may be formed along a periphery of the front panel, and the PCB assembly may be disposed in a region corresponding to the bezel so as to be hidden by the bezel.

In still another embodiment, a refrigerator according to an embodiment of the present invention comprises: a cabinet forming a storage space having a front opening; a door body configured to open and close the storage space; and a panel assembly detachably mounted to the door body, wherein the panel assembly comprises: a transparent front panel forming a front surface of the door; a transparent display mounted on a rear surface of the front panel; and a PCB assembly mounted to the front panel and disposed around a periphery of the transparent display, and the door body comprises: a front frame forming a front surface of the door body and defining a receiving space in which the panel assembly is accommodated; a door liner forming a rear surface of the door body and having an opening; and a body panel assembly including a plurality of transparent panels configured to cover the opening and allow viewing through a rear space of the door, wherein a heater is provided in the front frame to heat the receiving space.

In a state in which the panel assembly may be mounted to the door body, the PCB assembly may be positioned within the receiving space.

The body panel assembly may comprise: a front body panel forming a front surface and positioned within the receiving space; a rear body panel forming a rear surface and covering an opening of the door liner; and a spacer connecting the front body panel and the rear body panel to form an insulation layer, and the heater may be disposed along a periphery of the rear body panel.

The rear body panel may be formed larger than the front body panel, a protruded part extending outward may be formed along a periphery of the rear body panel, and the heater may be in contact with the protruded part.

A panel support portion extending to contact the body panel assembly may be formed on the front frame, and the heater may be disposed at an end of the panel support portion.

### BRIEF DESCRIPTION OF THE DRAWINGS

FIG. 1 is a front view of a refrigerator according to an embodiment of the present invention.

FIG. 2 is a perspective view of a door of the refrigerator.

FIG. 3 is an exploded perspective view from the front showing a state in which a panel assembly and a door body of the door are separated.

FIG. 4 is an exploded perspective view from the rear showing a state in which the panel assembly and the door body of the door are separated.

FIG. 5 is an exploded perspective view of the panel assembly.

FIG. 6 is a rear view of the panel assembly.

FIG. 7 is a perspective view of a first PCB assembly, which is one component of the panel assembly.

FIG. 8 is a perspective view of a second PCB assembly, which is another component of the panel assembly.

FIG. 9 is a perspective view of a side guide.

FIG. 10 is an enlarged view of portion A in FIG. 5.

FIG. 11 is an exploded perspective view of a third PCB assembly, which is one component of the panel assembly.

FIG. 12 is a sectional perspective view taken along line 12–12 of FIG. 4.

FIG. 13 is a cross-sectional view taken along line 13–13 of FIG. 2.

FIG. 14 is a sectional perspective view taken along line 14–14 of FIG. 2.

FIG. 15 is a partial perspective view showing an upper portion of the door body.

FIG. 16 is an exploded perspective view showing a wire arrangement of an upper end of the door and a top cover.

FIG. 17 is a block diagram showing a control signal flow of the refrigerator.

FIGS. 18A and 18B are views showing the display of the door in an ON state and an OFF state.

FIGS. 19A to 19D are views showing an example of a state change of a display window of the door.

FIGS. 20A to 20G are views showing another example of a state change of the display window.

FIG. 21 is a cross-sectional view of a door according to another embodiment of the present invention.

### DETAILED DESCRIPTION

Hereinafter, specific embodiments of the present invention will be described in detail with reference to the drawings. However, the present invention is not limited to the embodiments presented for illustrating the spirit of the invention, and various other embodiments falling within the scope of the inventive concept may be easily proposed through addition, modification, or deletion of other components without being retrogressive inventions.

Prior to the detailed description, directions used in the present specification will be defined.

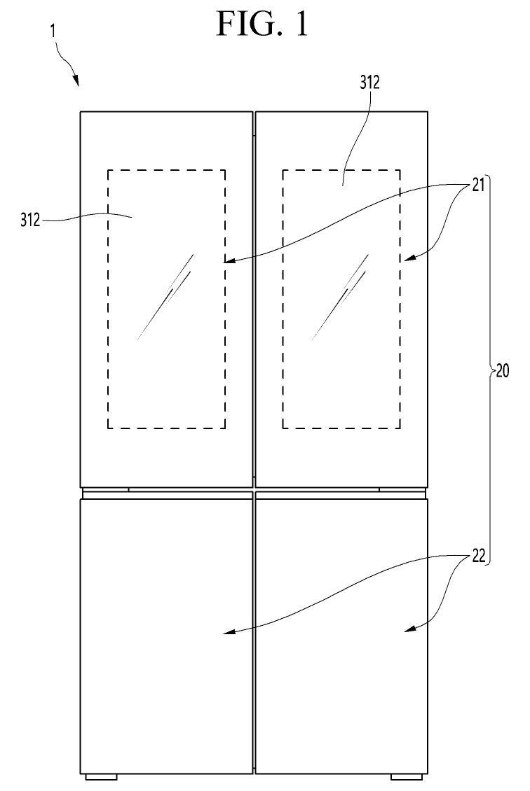

In an embodiment of the present invention, as shown in FIG. 1, a direction in which the front surface of the door faces is defined as a front direction, a direction toward the cabinet based on the front surface of the door is defined as a rear direction, a direction toward a floor surface on which the refrigerator is installed is defined as a downward direction, and a direction away from the floor surface is defined as an upward direction.

Furthermore, when referring to a direction not previously defined, the direction may be redefined and described based on each drawing.

FIG. 1 is a front view of a refrigerator according to an embodiment of the present invention.

As shown, a refrigerator 1 according to an embodiment of the present invention may include a cabinet 10 that forms a storage space, and a door 20 that opens and closes the storage space.

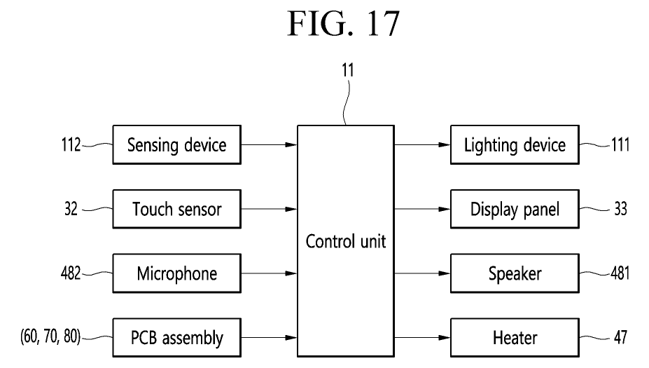

In one example, the cabinet 10 may have the storage space partitioned vertically. The storage space may be divided into an upper storage space and a lower storage space, where the upper storage space may serve as a refrigerating compartment, and the lower storage space may serve as a freezing compartment. The cabinet 10 may be provided with a control unit 11 (as shown in FIG. 17) that controls the overall operation of the refrigerator 1. The control unit 11 may be referred to as a main PCB (printed circuit board).

The door 20 may include an upper door 21 for opening and closing the upper storage space, and a lower door 22 for opening and closing the lower storage space. The upper door 21 may be referred to as a refrigerating compartment door or a first door, and the lower door 22 may be referred to as a freezing compartment door or a second door. The upper door 21 and the lower door 22 may form a pair of doors, and left and right ends of each door may be connected to the cabinet 10 by hinge devices, so that the storage spaces are opened and closed by rotation.

At least a portion of a front surface of the upper door 21 may be provided with a display window. The display window 312 may selectively allow viewing of a space at a rear side of the upper door 21. The display window may also be referred to as a screen or a transparent portion. In addition, the display window 312 may output images by a display 33 provided on the door 21. The display window 312 may be formed on each of a pair of left and right upper doors 21. Alternatively, the display window 312 may be formed only on one of the upper doors 21.

Hereinafter, the structure of the upper door 21 will be described in greater detail with reference to the drawings. For convenience of description, the upper door 21 may be referred to simply as the door 21.

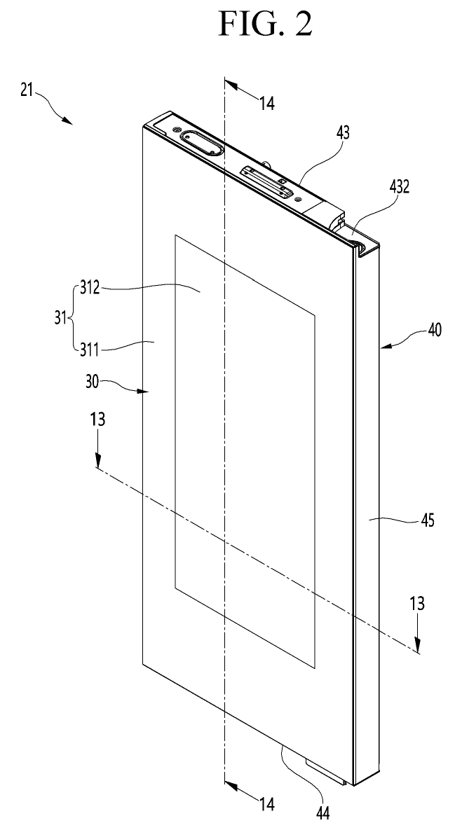

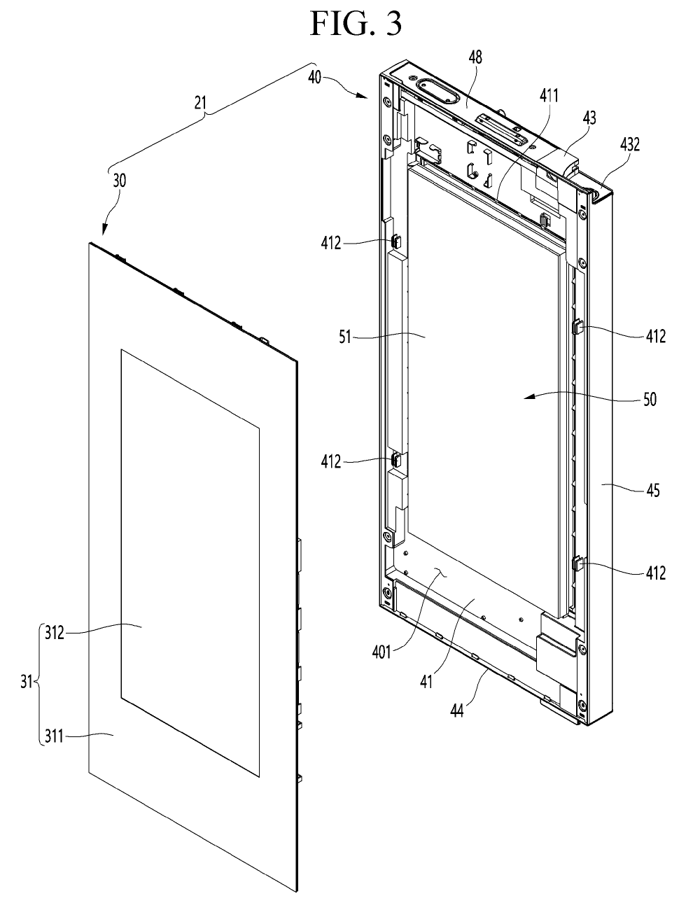

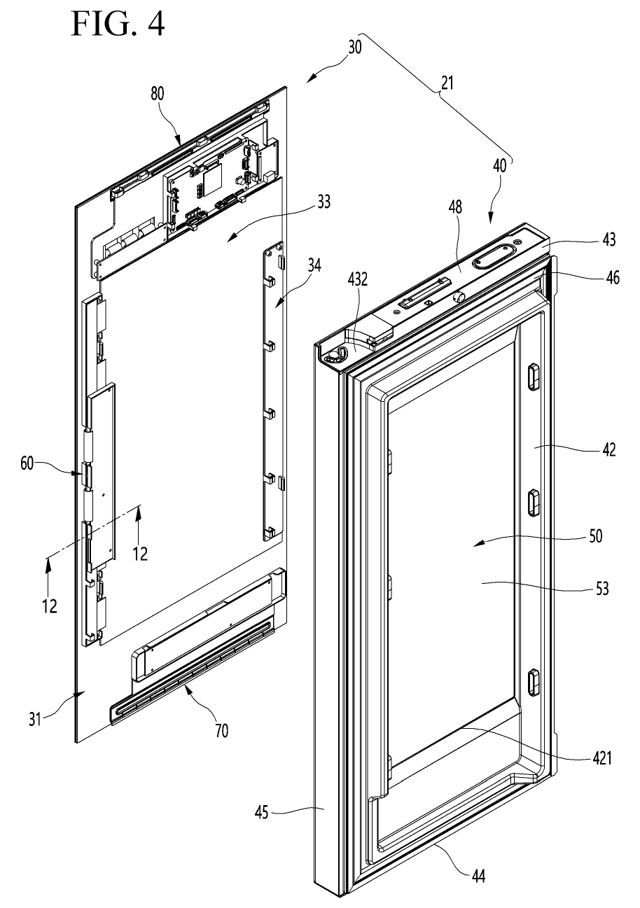

FIG. 2 is a perspective view of a door of the refrigerator, FIG. 3 is an exploded perspective view from the front showing a state in which a panel assembly and a door body of the door are separated, FIG. 4 is an exploded perspective view from the rear showing a state in which the panel assembly and the door body of the door are separated.

As shown, the door 21 may include a panel assembly 30 and a door body 40. The panel assembly 30 may have a structure detachably coupled to the door body 40.

In one example, the panel assembly 30 may be easily attached to and detached from the door body 40 without using separate tools to fasten fastening members such as screws or bolts. Accordingly, maintenance and assembly work of the panel assembly 30 can be facilitated.

The door body 40 may include a front frame 41 forming a front surface, a door liner 42 forming a rear surface, side frames 45 forming both side surfaces, and an upper cap 43 and a lower cap 44 forming an upper and a lower end, respectively.

In addition, the door body 40 may include a body panel assembly 50. The body panel assembly 50 may be composed of a plurality of transparent panels that allow viewing of the rear side of the door. The body panel assembly 50 may be referred to as a second panel assembly to distinguish it from the panel assembly 30.

The body panel assembly 50 may be disposed at the center of the door body 40. In addition, the body panel assembly 50 may form portions of both the front and rear surfaces of the door body 40.

A frame opening 411 through which the body panel assembly 50 passes may be formed in the front frame 41. A liner opening 421 through which the body panel assembly 50 passes may also be formed in the door liner 42. Accordingly, a front surface of the body panel assembly 50 may be exposed through the frame opening 411, and a rear surface of the body panel assembly 50 may be exposed through the liner opening 421. A gasket 46 may be provided along the periphery of the door liner 42.

In addition, a side restricting portion 412 for mounting the panel assembly 30 may be formed in the front frame 41. Side restricting protrusions 343 and 634 provided on both sides of the panel assembly 30 may be inserted into the side restricting portion 412. The side restricting portion 412 may be formed in a plurality along both sides of the body panel assembly 50 in an up-and-down direction.

The upper cap 43 and the lower cap 44 may be coupled to upper and lower ends of the panel assembly 30 to restrain the upper and lower ends of the panel assembly 30. Accordingly, in a state in which the panel assembly 30 is mounted to the door body 40, the upper and lower ends and both left and right sides of the panel assembly 30 are restrained, thereby maintaining a stable coupled state.

In addition, a portion of the front surface of the door body 40, that is, a portion of the front frame 41, may form a recessed receiving space 401 so that PCB assemblies 60, 70, and 80 protruding from the rear surface of the panel assembly 30 may be accommodated therein.

Although not shown, a lighting device 111 (as shown in FIG. 17) may be provided. By the operation of the lighting device 111, a rear space of the door 21 may be illuminated, thereby allowing the rear space to be viewed through the display window 312. In one example, the lighting device 111 may be provided on one side of the door liner 42 or the door body 40. In another example, the lighting device 111 may be provided on one side of the cabinet 10.

The panel assembly 30 may be detachably coupled to the door body 40 and may form a front surface of the door 21. The panel assembly 30 may be referred to as a door panel assembly. The panel assembly 30 may also be referred to as a second panel assembly to distinguish it from the body panel assembly 50. The panel assembly 30 may include a front panel 31 forming a front surface, and a display 33 and a plurality of PCB assemblies 60, 70, and 80 disposed at a rear side of the front panel 31.

The front panel 31 may be formed of a transparent material so as to be viewable therethrough. In one example, the front panel 31 may be formed of glass. In the embodiments of the present invention, the term “transparent” may be defined to include not only complete transparency but also a translucent state that allows viewing of a rear space to some extent. Likewise, the term “opaque” may be defined to include not only complete opacity but also a state in which the shape of the rear space is difficult to distinguish.

A display window 312 may be formed at the center of the front panel 31. Through the display window 312, the rear space of the door 21 may be viewed, and at the same time, an image displayed on the display 33 may be visible from the outside when the display 33 outputs a screen.

A bezel 311 may be formed along the periphery of the front panel 31. The bezel 311 may serve to cover components of the rear space and may be formed along the periphery of the display window 312. A plurality of PCB assemblies 60, 70, and 80 disposed along the periphery of the display 33 may be located within a region of the bezel 311 and thereby concealed by the bezel 311.

The PCB assemblies may include a first PCB assembly 80 positioned above the display 33, a second PCB assembly 70 positioned below the display 33, and a third PCB assembly 60 provided on one of the left and right sides of the display 33.

A side guide 34 may be provided on the other one of the left and right sides of the display 33. The side guide 34 may be disposed on one side of the left and right sides of the panel assembly 30 corresponding to a hinge mounting portion 432 at an upper end of the door 21.

Hereinafter, the panel assembly 30 will be described in greater detail with reference to the drawings.

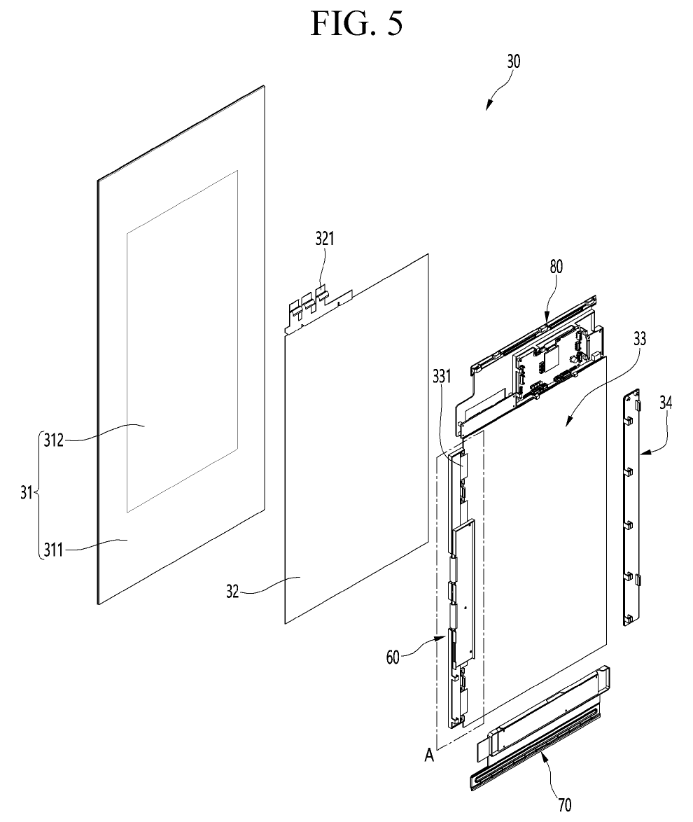

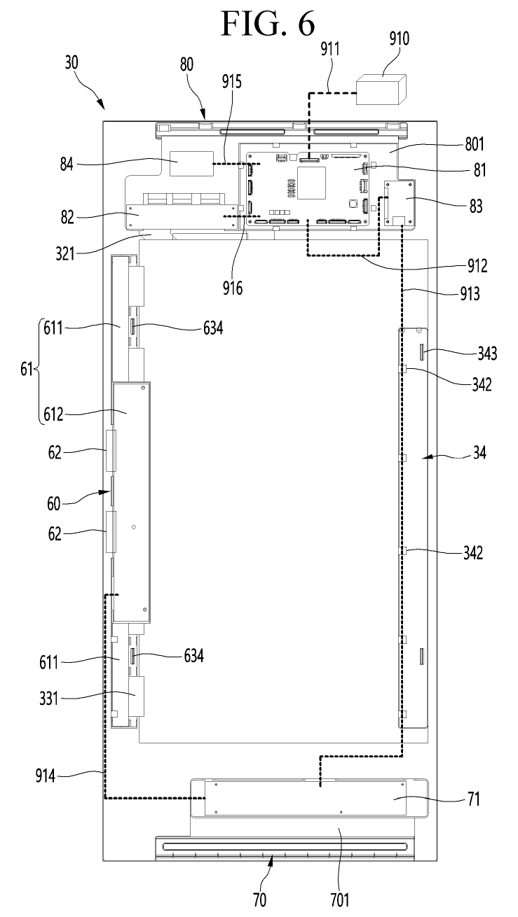

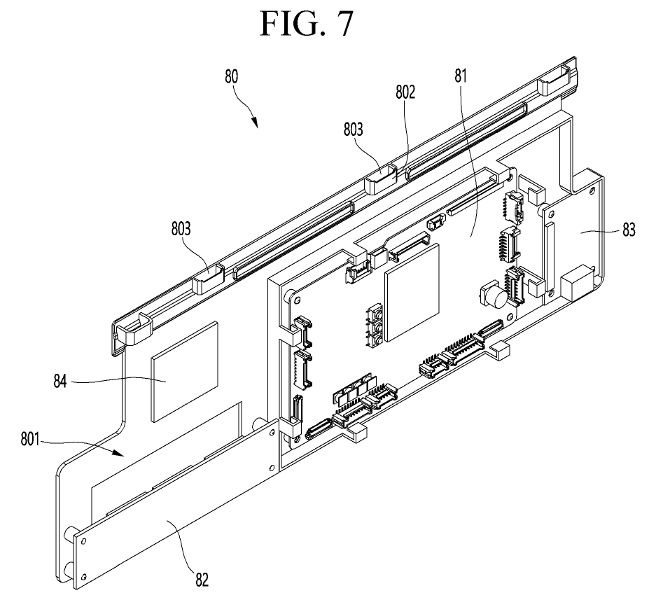

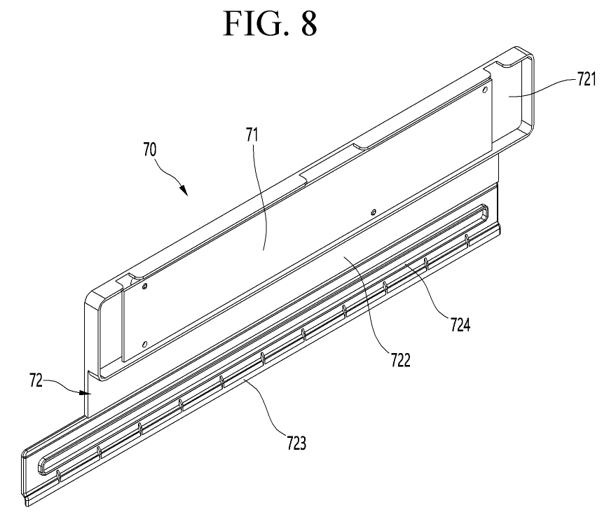

FIG. 5 is an exploded perspective view of the panel assembly, FIG. 6 is a rear view of the panel assembly, FIG. 7 is a perspective view of a first PCB assembly, which is one component of the panel assembly, FIG. 8 is a perspective view of a second PCB assembly, which is another component of the panel assembly.

As shown, the panel assembly 30 may include a front panel 31, a display 33, and a plurality of PCB assemblies 60, 70, 80. In addition, the panel assembly 30 may further include a touch sensor 32 configured to detect a user’s touch operation.

The touch sensor 32 may be disposed between the front panel 31 and the display 33. In one example, the touch sensor 32 may be formed in a film shape, with a front surface in contact with the front panel 31 and a rear surface in contact with the display 33. The touch sensor 32 may be formed at a position corresponding to the display window 312 and may have a corresponding size or a slightly larger size.

A touch cable 321 for transmitting a signal of the touch sensor 32 may be provided at an upper portion of the touch sensor 32. In one example, the touch cable 321 may be configured as a flat flexible cable (FFC). That is, the touch cable 321 may be formed in a film or flexible plate shape and may be connected to the first PCB assembly 80 disposed above.

The display 33 may be configured as a transparent display panel capable of both rearward visibility and image output, and may be referred to as a transparent display. The display 33 may also be referred to as a display panel. In one example, the display 33 may be configured as a transparent OLED panel. In particular, after an injection of foaming liquid into the door body 40, the panel assembly 30 including the transparent OLED (Organic Light-Emitting Diode) may be mounted, thereby preventing damage to the expensive OLED due to foaming heat. Furthermore, when the panel assembly 30 is detached, the transparent OLED may be exposed, thereby facilitating servicing of the high-cost transparent OLED.

The display 33 may be fixedly mounted to the front panel 31. Accordingly, when the panel assembly 30 is detached or mounted, the display 33 together with the plurality of PCB assemblies 60, 70, 80 may remain coupled to the front panel 31.

The display 33 may have a size corresponding to or slightly larger than that of the display window 312. A periphery of the display 33 may be spaced apart from the front panel 31, thereby providing a space in which the plurality of PCB assemblies 60, 70, 80 can be mounted along the periphery of the display 33.

A third PCB assembly 60 may be disposed at one of the left and right sides of the display 33. The third PCB assembly 60 may be connected to a side end of the display 33 by a display cable 331. In one example, the display cable 331 may be configured as a flat flexible cable (FFC). The third PCB assembly 60 may be provided on one of the left and right sides of the panel assembly 30 that is distant from the hinge mounting portion 432. The third PCB assembly 60 may be positioned between one end of the display 33 and the front panel 31, and a portion of the third PCB assembly 60 may overlap with a side end of the display 33.

A side guide 34 may be provided on the other one of the left and right sides of the display 33. The side guide 34 may be disposed between a side end of the display 33 and a side end of the front panel 31.

A first PCB assembly 80 may be disposed between an upper end of the display 33 and an upper end of the front panel 31. The first PCB assembly 80 may control all components disposed in the panel assembly 30 as a whole. The first PCB assembly 80 may be configured as a combination of a plurality of PCBs.

In detail, the first PCB assembly 80 may include a first PCB bracket 80 mounted on a rear surface of the front panel 31, and a plurality of PCBs 81, 82, 83, 84 mounted on the first PCB bracket 80.

The first PCB bracket 80 may be formed in a plate shape. An upper restricting portion 802 and an upper restricting groove 803 may be formed at an upper end of the first PCB bracket 80. A plurality of upper restricting grooves 803 may be arranged along the upper end of the first PCB bracket 80. When a cap cover 48 is mounted, upper restricting protrusions 483 formed on the cap cover 48 may be inserted into the upper restricting grooves 803 to restrain an upper portion of the panel assembly 30.

The first PCB bracket 80 may be provided with a panel PCB 81, a touch PCB 82, and a converter PCB 83. In addition, the first PCB bracket 80 may further be provided with a thread PCB 84.

The panel PCB 81 may be configured to control the overall operation of the panel assembly 30 and may be directly or indirectly connected to the plurality of PCBs 82, 83, and 84 by cables. A panel cable 911 extending outward from the door may be connected to the panel PCB 81 to be linked with the control unit 11 of the cabinet 10. One end of the panel cable 911 may be provided with a connector 910, which can be easily connected to and disconnected from a door cable 921 provided in the door body 40 when the panel assembly 30 is attached or detached.

A converter PCB 83 may be provided to perform signal conversion between the panel PCB 81 and a scale PCB 71 of the second PCB assembly 70. The converter PCB 83 may be arranged separately from the panel PCB 81 and may be connected thereto through a first connection cable 912. The converter PCB 83 may also be connected to the scale PCB 71 through a second connection cable 913. In this case, the second connection cable 913 may pass along the side guide 34 and through a cable guide 342 of the side guide 34.

A thread module 84 may be provided on one side of the panel PCB 81. The thread module 84 may be used for communication with an external device and may be configured as a separate PCB connected to the panel PCB 81 through a fourth connection cable 915.

The touch PCB 82 may be configured separately from the panel PCB 81. The touch PCB 82 may be connected to the panel PCB 81 through a fifth connection cable 916, and a touch cable 321 may be connected to another side of the touch PCB 82.

Meanwhile, the first PCB assembly 80 may be connected to the control unit 11 via a cable. The first PCB assembly 80 may also be connected to the second PCB assembly 70, and the second PCB assembly 70 may be connected to the third PCB assembly 60. That is, the third PCB assembly 60 and the second PCB assembly 70 may be directly or indirectly connected to the first PCB assembly 80, and may be connected to the control unit 11 through the first PCB assembly 80.

A second PCB assembly 70 may be provided below the display 33. The second PCB assembly 70 may be disposed between a lower end of the display 33 and a lower end of the front panel 31. The second PCB assembly 70 may be used to drive the display 33, and in particular, may control driving of the transparent OLED panel.

In detail, the second PCB assembly 70 may include a second PCB bracket 72 mounted on a rear surface of the front panel 31, and a scale PCB 71 mounted on the second PCB bracket 72.

The second PCB bracket 72 may be formed in a plate shape and may be attached to the rear surface of the front panel 31. A PCB mounting portion 721, on which the scale PCB 71 is mounted, may be formed at an upper portion of the second PCB bracket 72.

A bracket extension portion 722 may be formed to extend downward from a lower end of the PCB mounting portion 721. A lower restricting portion 723 may be formed at a lower end of the bracket extension portion 722, that is, at a lower end of the second PCB bracket 72. The lower restricting portion 723 may be coupled to the lower cap 44 and may restrain a lower portion of the panel assembly 30.

A lower restricting groove 725 opened downward may be formed in the lower restricting portion 723. A lower restricting protrusion 442, which protrudes upward from the lower cap 44, may be inserted into the lower restricting groove 725. By engagement between the lower restricting protrusion 442 and the lower restricting groove 725, the lower portion of the panel assembly 30 may be maintained in a state of being coupled to the door body 40.

A support rib 724 protruding rearward may be formed above the lower restricting groove 725. The support rib 724 may come into contact with a front surface of the door body 40, thereby preventing the panel assembly 30 from moving in the front–rear direction and allowing it to maintain a stable mounting position.

The third PCB assembly 60 may be connected to a side end of the display 33. The third PCB assembly 60 may include a source PCB 611 and a T-con PCB 612, at least some of which may be arranged in succession. The third PCB assembly 60 may be configured in multiple stages so that the plurality of PCBs 611 and 612 can be arranged within a limited space. The source PCB 611 and the T-con PCB 612 may collectively be referred to as side PCBs.

The scale PCB 71 may transmit a signal of the second PCB assembly 70, which is connected to the display 33, to the converter PCB 83. One side of the scale PCB 71 may be connected to the converter PCB 83 through the second connection cable 913, and the other side of the scale PCB 71 may be connected to the third PCB assembly 60.

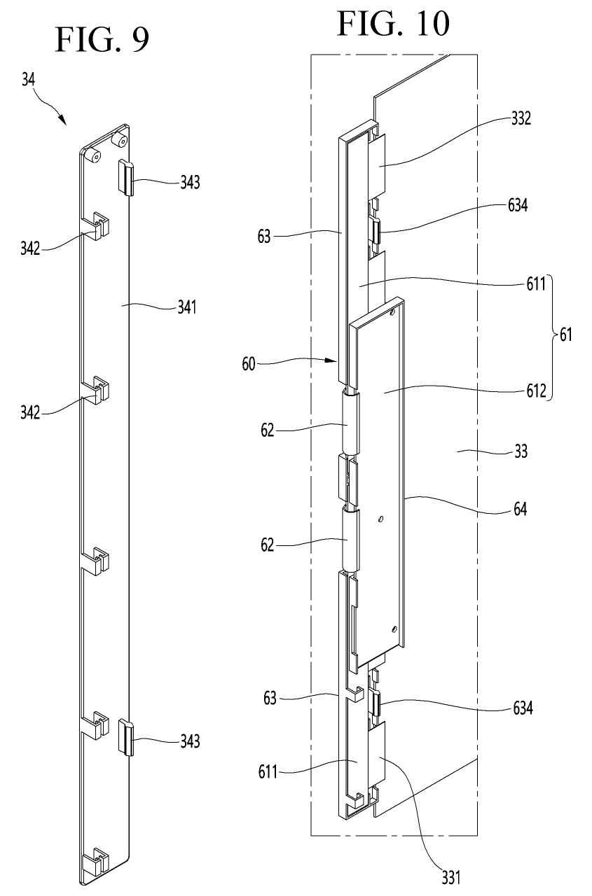

FIG. 9 is a perspective view of a side guide.

As shown, the side guide 34 may extend vertically along a side of the front panel 31. The side guide 34 may include a plate-shaped side body 341, a cable guide 342 protruding rearward from a rear surface of the side body 341, and a side restricting protrusion 343.

The side body 341 may be formed in a plate shape and may be attached to a rear surface of the front panel 31. A plurality of cable guides 342 may be arranged along the side body 341 in a vertical direction. The cable guides 342 may be aligned on a common vertical line. Each cable guide 342 may have a rear portion opened so that the second connection cable 913 can enter and exit. In addition, the cable guides 342 may be opened vertically such that the second connection cable 913 passes through the cable guides 342 and is guided in the vertical direction.

A plurality of side restricting protrusions 343 may be formed in a vertical direction and may be arranged at positions corresponding to the side restricting portions 412 to be insertable thereinto. The side restricting protrusions 343 may be formed in a hook shape and may be engaged or press-fitted within the side restricting portions 412, thereby restraining one side end of the panel assembly 30. The side restricting protrusions 343 may be arranged at intervals in the vertical direction. In one example, the side restricting protrusions 343 may be provided at upper and lower portions of the side body 341.

Accordingly, the third PCB assembly 60 may be arranged along a periphery of the display 33 by cables 912, 913, 914, which connect the lower second PCB assembly 70 and the upper first PCB assembly 80 through the lateral side guide 34.

Hereinafter, the third PCB assembly 60 will be described in more detail with reference to the drawings.

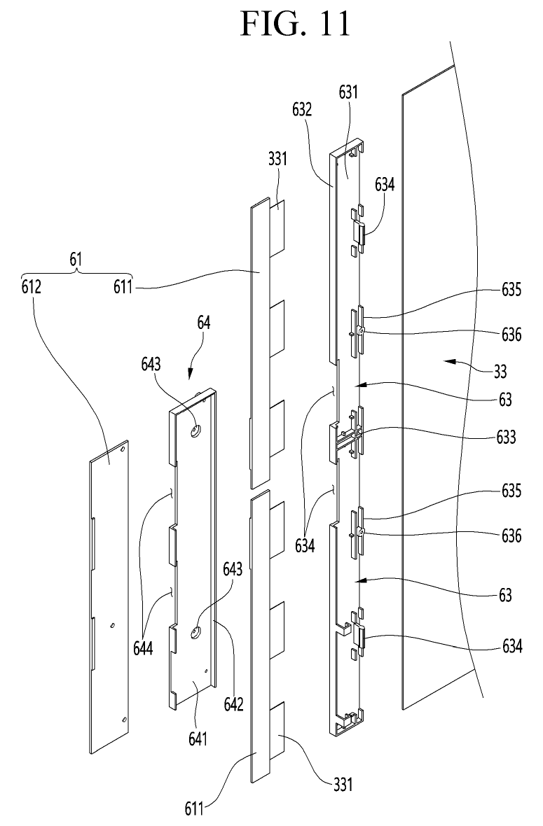

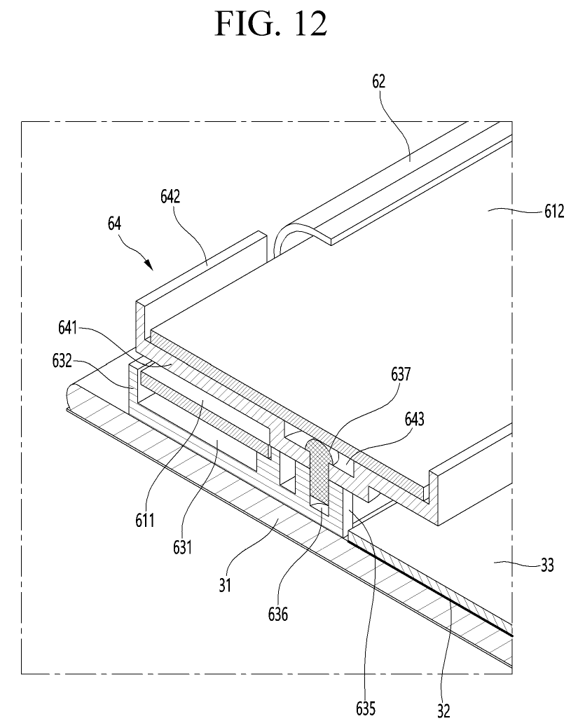

FIG. 10 is an enlarged view of portion A in FIG. 5, FIG. 11 is an exploded perspective view of a third PCB assembly, which is one component of the panel assembly, FIG. 12 is a sectional perspective view taken along line 12–12 of FIG. 4.

As shown, the third PCB assembly 60 may be composed of a plurality of PCBs 611, 612, which may be three-dimensionally stacked and arranged in alignment.

In one example, the PCBs 611 and 612 may include a source PCB 611 connected to the display 33 to drive the display 33, and a T-con (timing controller) PCB 612 connected to the source PCB 611 and the scale PCB 71 to transmit driving commands for the display 33 to the source PCB 611. The source PCB 611 may be referred to as a first PCB, and the T-con PCB 612 may be referred to as a second PCB or a timing control PCB.

The source PCBs 611 may be disposed as an upper and lower pair at one side end of the display 33. Each source PCB 611 may be connected to the display 33 by a display cable 331, which may be a flat flexible cable. A plurality of source PCBs 611 may be arranged vertically in alignment. Of course, two or more source PCBs 611 may be provided, depending on design requirements.

The T-con PCB 612 may be disposed behind the source PCB 611, and when viewed from the rear, the T-con PCB 612 and the source PCB 611 may be arranged in a stacked structure. In addition, at least a portion of the T-con PCB 612 and the source PCB 611 may overlap each other when viewed from the rear.

One side end of the source PCB 611 and one side end of the T-con PCB 612 may be connected to each other by a connection cable 62. The connection cable 62 may be formed of a flexible cable and may be bent in a vertical direction to connect one sides of the source PCB 611 and the T-con PCB 612, which are located closer to a side edge of the front panel 31. In one example, the connection cable 62 may be a flat flexible cable (FFC).

In this case, the source PCB 611 and the T-con PCB 612 may be positioned in a rear region of the bezel 311 while being stacked in a front–rear direction. Therefore, when viewed from the front, the T-con PCB 612, the source PCB 611, and the connection cable 62 may not be exposed.

The second PCB assembly 70 may include a source case 63 and a T-con case 64, which may also be referred to as a first case and a second case, respectively.

The source case 63 may include a first base 631 attached to a rear surface of the front panel 31 and configured to accommodate the source PCB 611, and a first flange 632 protruding rearward along a periphery of the first base 631. The first flange 632 may be formed partially along a portion of the entire periphery of the first base 631. The source PCB 611 may be disposed within a space defined by the first flange 632. Accordingly, even when the T-con PCB 612 and the T-con case 64 are stacked, interference with the source PCB 611 may be prevented.

A first opening 634 through which the connection cable 62 enters and exits may be formed along a periphery of the first flange 632. A case support portion 635 for supporting the T-con case 64 may be formed on the first base 631. A fastening hole 636, through which a fastening member penetrates the source case 63, may be formed in the case support portion 635. A plurality of case support portions 635 may be formed along the first base 631 in a vertical direction.

A side restricting protrusion 634 protruding rearward and coupled to the door body 40 may be formed on the first base 631. The side restricting protrusion 634 may be formed in a hook-like structure and may be inserted into the side restricting portion 412. A plurality of side restricting protrusions 634 may be formed along the first base 631 in the vertical direction. The side restricting protrusions 634 may be positioned at locations corresponding to the side restricting portions 412. The side restricting protrusion 634 may have the same shape as the side restricting protrusion 343 formed on the side guide 34. To distinguish it from the side restricting protrusion 343 of the side guide 34, the side restricting protrusion 634 may be referred to as a case side protrusion.

Meanwhile, the source case 63 may be formed in a number corresponding to that of the source PCBs 611. In one example, the source case 63 may consist of two separate cases, each configured to accommodate a corresponding source PCB 611. In this case, a connection portion 633 may be formed between a lower end of the upper source case 63 and an upper end of the lower source case 63, thereby connecting the two cases together. Of course, the source case 63 may alternatively be configured as a single structure in which the two source PCBs 611 are both mounted within one common source case 63.

The T-con case 64 may be positioned behind the source case 63 and may include a second base 641 configured to accommodate the T-con PCB 612, and a second flange 642 protruding rearward along a periphery of the second base 641.

The second flange 642 may be partially formed along a portion of the entire periphery of the second base 641. The T-con PCB 612 may be disposed within a space defined by the second flange 642. Accordingly, the T-con PCB 612 may not interfere with the source case 63 and the source PCB 611 disposed below it.

An second opening 644, through which the connection cable 62 enters and exits, may be formed along a periphery of the second flange 642. The T-con case 64 may be formed to have a size corresponding to that of the T-con PCB 612 and smaller than that of the source PCB 611. In addition, the T-con case 64 may be positioned between an upper and a lower pair of the source PCBs 611 arranged vertically. Therefore, the first opening 634 and the second opening 644 may be aligned with each other in a front–rear direction.

fastening portion 643, into which a fastening member 637 such as a screw is fastened, may be formed on a rear surface of the second base 641 corresponding to the case support portion 635. The fastening portion 643 may be recessed forward and opened so that the fastening member 637 can pass therethrough. When the T-con case 64 is aligned in front of the source case 63, the fastening portion 643 may be aligned with the fastening hole 636.

The first PCB assembly 80, second PCB assembly 70, side guide 34, and third PCB assembly 60 may be arranged along a periphery of the display 33, and may be disposed along a rear periphery of the front panel 31. The first PCB assembly 80, second PCB assembly 70, side guide 34, and third PCB assembly 60 may project farther rearward than the display 33 and may be accommodated in a recessed space formed in a front surface of the door body 40.

Hereinafter, with reference to the drawings, a detailed description will be given of a mounting structure of the door body 40 and the display 33.

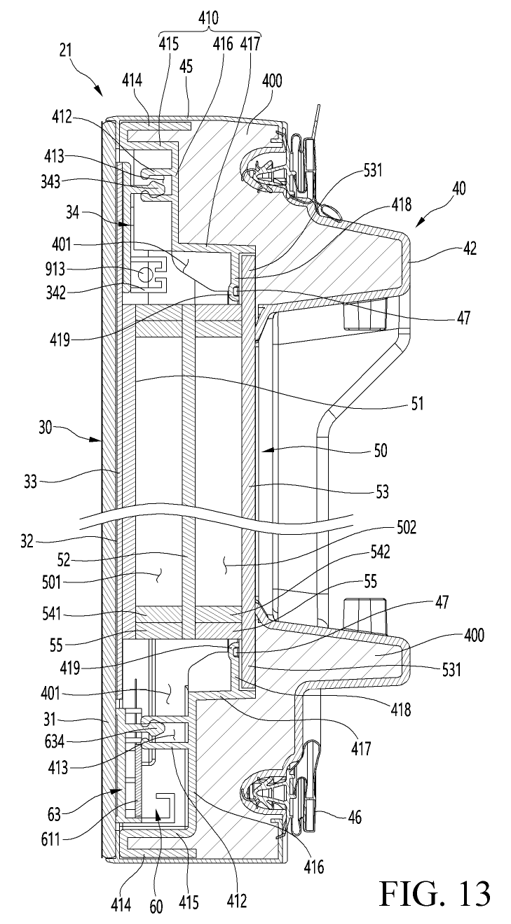

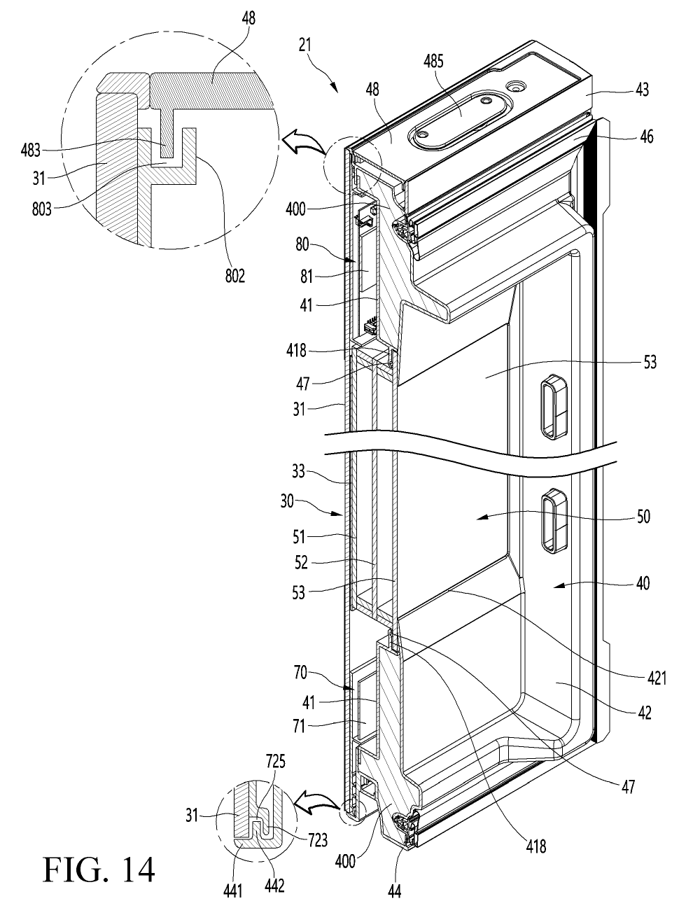

FIG. 13 is a cross-sectional view taken along line 13–13 of FIG. 2, FIG. 14 is a sectional perspective view taken along line 14–14 of FIG. 2.

As illustrated, the door body 40 may have an insulation layer 400 formed therein by filling a foaming agent inside the assembly in which the front frame 41, door liner 42, side frame 45, upper cap 43, lower cap 44, and body panel assembly 50 are coupled together. That is, a central portion of the door body 40 may be configured to allow a rear space to be visible through the body panel assembly 50, and a peripheral portion of the door body 40 outside the body panel assembly 50 may be thermally insulated by the insulation layer 400.

The body panel assembly 50 may be formed of a plurality of transparent panels. For example, the body panel assembly 50 may include a first panel 51 forming a front surface, a third panel 53 forming a rear surface, and a second panel 52 interposed between the first panel 51 and the third panel 53. The first panel 51, second panel 52, and third panel 53 may be formed of a transparent glass material. At least a portion of the first panel 51, second panel 52, and third panel 53 may be composed of low-emissivity (Low-e) glass. The first panel 51 may be referred to as a front body panel, the second panel 52 as a middle body panel, and the third panel 53 as a rear body panel.

A first spacer 541 may be provided between the first panel 51 and the second panel 52 to connect the first panel 51 and the second panel 52. The first spacer 541 may be formed along a periphery of the first panel 51 and the second panel 52. A sealant 55 may be applied to an outer side of the first spacer 541 to further seal end portions of the first panel 51, the second panel 52, and the first spacer 541. Accordingly, a space between the first panel 51 and the second panel 52 may be hermetically sealed to form a first insulation layer 501. The first insulation layer 501 may be in a vacuum state or filled with an insulating gas.

A second spacer 542 may be provided between the second panel 52 and the third panel 53 to connect the second panel 52 and the third panel 53. The second spacer 542 may be formed along a periphery of the second panel 52 and the third panel 53. A sealant 55 may be applied to an outer side of the second spacer 542 to further seal end portions of the second panel 52, the third panel 53, and the second spacer 542. Accordingly, a space between the second panel 52 and the third panel 53 may be hermetically sealed to form a second insulation layer 502. The second insulation layer 502 may be in a vacuum state or filled with an insulating gas.

Meanwhile, the body panel assembly 50 may also have a structure in which the first panel 51 and the third panel 53 are combined to form a single insulated space.

A total thickness of the body panel assembly 50 may not project beyond a front end of the door body 40. In a state in which the panel assembly 30 is mounted, the display 33 and the first panel 51 may be disposed to face each other. In this mounted state, a rear surface of the display 33 and a front surface of the first panel 51 may come into contact with each other, and a central portion of the panel assembly 30 may be supported by the door body 40.

Meanwhile, a protruded part 531 may be formed along a periphery of a rear surface of the body panel assembly 50, that is, along a periphery of the third panel 53. The protruded part 531 may form an end of the third panel 53 and may protrude outward beyond the second spacer 542 to come into contact with the front frame 41. A heater 47 may be disposed on the protruded part 531.

In detail, the first panel 51 and the second panel 52 may have the same size, and the third panel 53 may be formed larger than the first panel 51 and the second panel 52. Accordingly, the protruded part 531 may protrude farther outward than the first panel 51 and the second panel 52.

In a state in which the body panel assembly 50 is mounted, a rear surface of the third panel 53 may come into contact with and be supported by a portion of the door liner 42 that defines the liner opening 421. A front surface of the third panel 53 may be supported by an end portion of the front frame 41. That is, the protruded part 531 may protrude outward beyond the liner opening 421 such that a rear side of the protruded part 531 contacts the insulation layer 400, while a front side thereof contacts the front frame 41 and the heater 47.

The body panel assembly 50 may be fixed to the door body 40 by the protruded part 531, and the heater 47 mounted on the protruded part 531 may prevent condensation inside the receiving space 401.

A front periphery of the door body 40 may be formed by the front frame 41. The front frame 41 may be disposed at a position corresponding to a peripheral region of the body panel assembly 50, and may form the receiving space 401 in which components disposed at a rear side of the panel assembly 30 can be received.

The front frame 41 may be formed in a rectangular frame shape, and an outer periphery of the front frame 41 may be connected to the side frame 45, the upper cap 43, and the lower cap 44. An frame opening 411 may be formed at an inner side of the front frame 41 such that the body panel assembly 50 can pass therethrough.

In detail, the front frame 41 may include a frame side portion 414. The frame side portion 414 may be coupled to the side frame 45. The frame side portion 414 may be bent to support a rear periphery of the front panel 31.

The front frame 41 may further include a frame receiving portion 410 for forming the receiving space 401. The frame receiving portion 410 may be bent multiple times. The receiving space 401 may thus form a multi-stepped recessed space by means of the frame receiving portion 410.

For example, the frame receiving portion 410 may include a first part 415 extending rearward and a second part 416 extending from the first part 415 toward a periphery of the body panel assembly 50. The second part 416 may form a surface facing a rear surface of the front panel 31.

A side restricting portion 412 may be formed on the second part 416, protruding forward. A side restricting groove 413 recessed rearward may be formed in the side restricting portion 412. For example, the side restricting portion 412 may be composed of a pair of spaced ribs, and the side restricting groove 413 may be formed between the pair of ribs. The side restricting projections 343 and 634 may be press-fitted into the side restricting groove 413. To this end, an end of the side restricting portion 412 may be formed in a hook shape so as to engage with the side restricting projections 343 and 634.

A plurality of side restricting portions 412 may be provided on both left and right sides of the front frame 41 and may be formed at positions corresponding to the side restricting projections 343 and 634. Accordingly, without any additional fastening operation, when the panel assembly 30 is aligned and pushed into the receiving space 401, both lateral ends of the panel assembly 30 may be fixed to the door body 40.

The frame receiving portion 410 may include a third part 417 extending rearward from an end of the second part 416. The third part 417 may extend to the third panel 53. The third part 417 may come into contact with an outer end of the third panel 53 to support the body panel assembly 50.

A panel support portion 418 may be formed on the front frame 41. The panel support portion 418 may extend from the frame receiving portion 410 toward the body panel assembly 50. For example, the panel support portion 418 may extend from the third part 417. The panel support portion 418 may extend toward the body panel assembly 50 from a position spaced forward from an end of the third part 417.

The panel support portion 418 may extend to contact a front surface of the third panel 53, and may also extend to contact the protruded part 531. Accordingly, an end portion of the third panel 53 may be supported by the panel support portion 418 and the third part 417.

The panel support portion 418 may extend up to the sealant 55. A heater mounting portion 419, in which the heater 47 is accommodated, may be formed at an end of the panel support portion 418. The heater mounting portion 419 may be recessed such that the heater 47 can be inserted therein. Therefore, in a state where the heater 47 is mounted in the heater mounting portion 419, the heater 47 may come into contact with a peripheral surface of the third panel 53 and heat an end portion of the third panel 53.

The panel support portion 418 and the heater 47 may be formed along a periphery of the body panel assembly 50. Accordingly, when the heater 47 is operated, a periphery of the third panel 53 may be heated, thereby preventing cold air from being transmitted into the receiving space 401 and preventing condensation from occurring within the receiving space 401. That is, the PCB assemblies 60, 70, and 80 of the panel assembly 30, which are exposed within the receiving space 401, may be prevented from being damaged by condensation inside the receiving space 401.

The front frame 41 may be injection-molded of a plastic material, and may integrally form both a structure for accommodating and fixing the panel assembly 30 and a structure for fixing the body panel assembly 50 in a single configuration.

Meanwhile, a lower support portion 441 for supporting a lower end of the panel assembly 30 may protrude from the lower cap 44. A lower restricting projection 442 may be formed on the lower support portion 441 so as to protrude upward. A lower restricting groove 725, into which the lower restricting projection 442 is inserted, may be formed at a lower end of the second PCB bracket 72 of the panel assembly 30. Accordingly, in a state where the panel assembly 30 is disposed within the receiving space 401 of the door body 40, a lower portion of the panel assembly 30 may be supported by the lower support portion 441, and a restrained state may be maintained by engagement between the lower restricting projection 442 and the lower restricting groove 725.

A upper opening 431, into which an upper restricting portion 802 of the first PCB bracket 80 is inserted, may be formed on a front surface of the upper cap 43. In a state where the panel assembly 30 is disposed on the door body 40, the upper restricting portion 802 may be positioned inside the upper cap 43. An upper restricting groove 803 formed on an upper surface of the upper restricting portion 802 may be exposed through an opened upper surface of the upper cap 43. When a cap cover 48 is mounted, an upper restricting projection 483 formed on the cap cover 48 may be inserted into the upper restricting groove 803.

Accordingly, in a state where the panel assembly 30 is mounted to the door body 40, when the upper restricting groove 803 is exposed above the upper cap 43, the cap cover 48 may be coupled to the upper cap 43 to restrain an upper portion of the panel assembly 30.

As described above, the panel assembly 30 may be restrained at its upper end, lower end, and both lateral ends by the door body 40. In a state where mounting of the panel assembly 30 is completed, a rear surface of the panel assembly 30, that is, the display 33, may be supported by a front surface of the body panel assembly 50. Furthermore, the PCB assemblies 60, 70, and 80 disposed along a periphery of the panel assembly 30 may be positioned within the receiving space 401.

Meanwhile, during mounting of the panel assembly 30, cables may be detachably connected for electrical connection among components of the panel assembly 30. That is, during attachment or detachment of the panel assembly 30, connection and disconnection operations of the cables may be performed together.

Hereinafter, with reference to the drawings, a configuration of the cables of the panel assembly 30, their connections, and a cable arrangement structure of the door body 40 will be described.

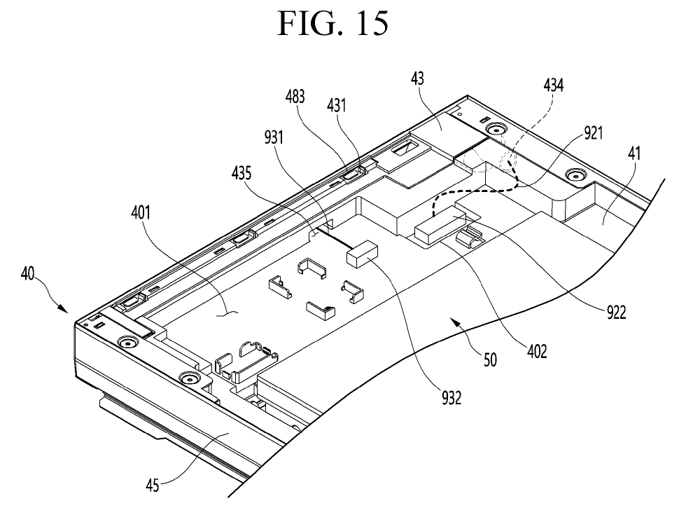

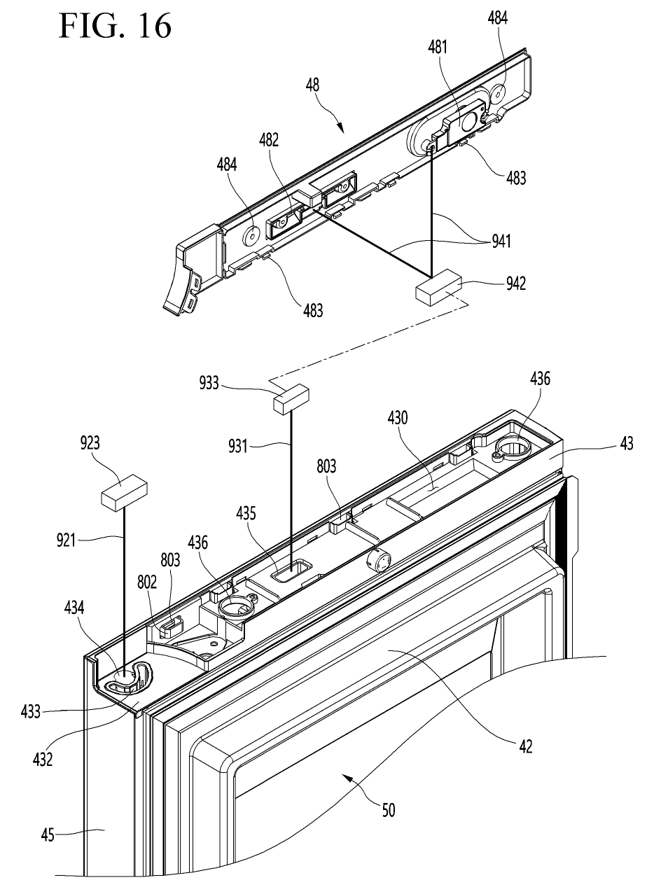

FIG. 15 is a partial perspective view showing an upper portion of the door body, FIG. 16 is an exploded perspective view showing a wire arrangement of an upper end of the door and a top cover.

As illustrated, a hinge mounting portion 432, on which a hinge device for rotatably connecting the door 21 to the cabinet 10 is mounted, may be recessedly formed at one end of an upper surface of the door 21. The hinge mounting portion 432 may be formed at one end of the upper cap 43.

A hinge hole 433, into which a rotational shaft of the hinge device is inserted, may be formed in the hinge mounting portion 432. In addition, a wire hole 434, through which a door cable 921 passes, may be formed at one side of the hinge hole 433.

The door cable 921 may be provided with connectors 922 and 923 at both ends thereof. The connector 923 may be connected to one end of the door cable 921 that extends outward through the hinge mounting portion 432 of the door body 40, and may be easily connected to a cable connected to a control unit 11 of the cabinet 10. That is, when the door 21 is separated or mounted, the door cable 921 may be detachably connected and disconnected.

A connector 922 may be provided at the other end of the door cable 921, and may be exposed through a connector opening 402 formed at an upper portion of an receiving space 401 of the door body 40. Accordingly, during mounting of the panel assembly 30, a connector 910 provided at a panel cable 911 of the panel assembly 30 may be connected to the connector 922 of the door cable 921 within the receiving space 401. That is, during the mounting process of the panel assembly 30, the cable 911 connected to the panel assembly 30 may be simply connected and disconnected without directly passing through the door body 40 or being connected to the control unit 11 of the cabinet 10.

Meanwhile, a cap space 430 recessed inward may be formed on an upper surface of the upper cap 43, and a cap through-hole 435, through which a cover connection cable 931 passes, may be formed inside the cap space 430. The cap through-hole 435 may be opened so that the cap space 430 and the receiving space 401 communicate with each other, and the cover connection cable 931 may pass therethrough.

A connector 932 may be provided at one end of the cover connection cable 931, and the connector 932 may be connected to the first PCB assembly 80. The other end of the cover connection cable 931 may extend into the cap space 430, and a connector 933 provided at an end of the cover connection cable 931 may be connected to a connector 942 of a cover cable 941 connected to the cap cover 48.

Meanwhile, foam injection ports 436 may be opened at both sides of an upper surface of the upper cap 43. The foam injection ports 436 may be opened at both ends of the cap space 430, so that a foaming liquid can be injected into the interior of the door body 40.

A cap cover 48 may be mounted on the upper surface of the upper cap 43. The cap cover 48 may shield the cap space 430 and form a portion of the upper surface of the door 21.

A plurality of upper engagement protrusions 483, which are inserted into the upper engagement grooves 802, may be formed on a lower surface of the cap cover 48. In addition, cover fastening holes 484, into which fastening members for fixing the cap cover 48 to the upper cap 43 are fastened, may be formed on both sides of the cap cover 48.

Meanwhile, the cap cover 48 may be provided with a microphone 482 for receiving a user’s voice command and a speaker 481 for outputting sound. The microphone 482 and the speaker 481 may be fixedly mounted on the lower surface of the cap cover 48 and connected to a cover cable 941. A connector 942 may be provided at an end of the cover cable 941. Accordingly, when the cap cover 48 is mounted on the upper cap 43, the connector 942 of the cover cable 941 may be connected to a connector 933 of the cover connection cable 931.

A microphone hole may be opened at a position of the cap cover 48 corresponding to the microphone 482 so that a user’s voice can be delivered to the microphone 482. In addition, the cap cover 48 may be provided with a speaker cover 485 that shields the speaker 481 from above.

Hereinafter, the operation of the refrigerator 1 according to an embodiment having the above-described structure will be described in detail with reference to the drawings.

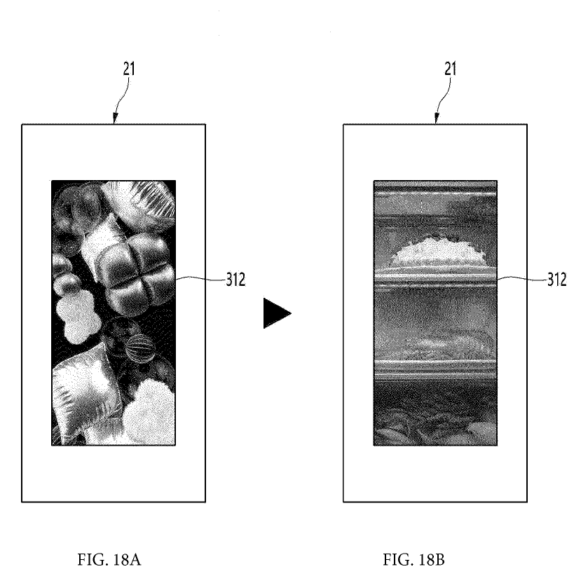

FIG. 17 is a block diagram showing a control signal flow of the refrigerator, FIGS. 18A and 18B are views showing the display of the door in an ON state and an OFF state.

As illustrated, in the refrigerator 1 according to the embodiment of the present invention, the state of the display window 312 may variously change depending on the operation of the display 33.

The operations of the display 33, a door light 111, a speaker 481, and a heater 47 may be controlled by the control unit 11. In addition, depending on a user’s manipulation detected by the touch sensor 32, the user’s approach or manipulation detected by a sensing device 112, or recognition of a user’s voice command input through the microphone 482, the control unit 11 may control the operation of the refrigerator 1. The sensing device 112 may include a knock sensor, a proximity sensor, or an illuminance sensor.

For example, when the display 33 is turned off and the display panel 32 is not operating, the display window 312 may be opaque, and a rear space of the door 21 may appear dark, such that the rear space of the door 21 is not visible through the display window 312. At this time, the lighting device 111 may be in an off state.

When a user performs a touch operation on the display window 312, the display 33 may be turned on due to detection by the touch sensor 32. When the display 33 is turned on, as shown in FIG. 18A, a screen output from the display 33 is displayed through the display window 312, and the user can view the screen. When the lighting device 111 is turned off, a space behind the door 21 may not be visible through the display window 312.

When the user performs a touch operation on the display window 312, the lighting device 111 may be turned on due to detection by the touch sensor 32. When the lighting device 111 is turned on, as shown in FIG. 18B, a space behind the door 21 becomes bright, and the display window 312 may visualize the rear space of the door 21.

Meanwhile, when both the display 33 and the lighting device 111 are turned on, the space behind the door 21 becomes visible through the display window 312, and simultaneously, the display 33 can output an image. That is, the display window 312 can output an image on the transparent display 33 while the rear space of the door 21 is visible.

The operations of the display 33 and the lighting device 111 may be controlled not only by the operation of the touch sensor 32, but also through detection by the sensing device 112, voice input via the speaker 481, or input from other operating devices or remote devices provided in the refrigerator.

By utilizing such various screen output states, the display window 312 can provide the user with diverse usage environments. Hereinafter, examples of state changes of the display window 312 will be described with reference to the drawings.

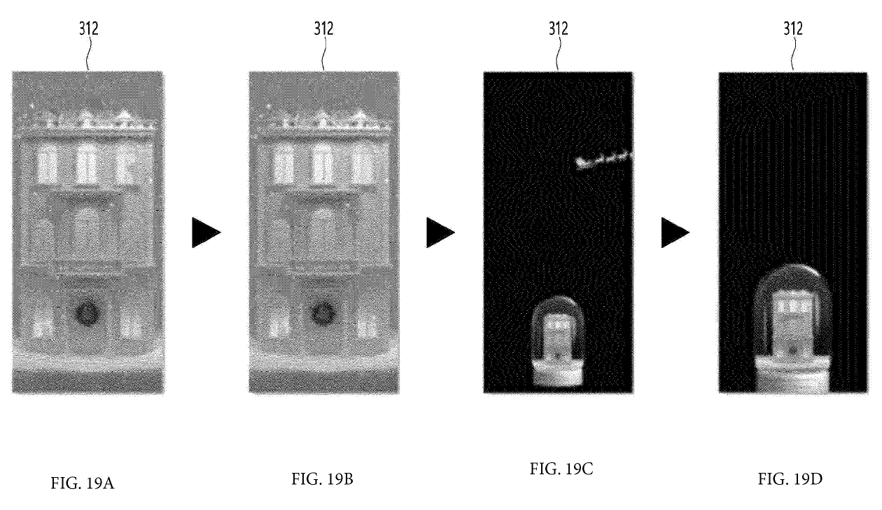

FIGS. 19A to 19D are views showing an example of a state change of a display window of the door.

As illustrated, the refrigerator 1 may transition from a specific screen state to another screen state according to a user’s operation.

Specifically, as shown in FIG. 19A, the display 33 may operate to output a specific screen. For example, until a specific user operation is input, the display 33 may output a certain screen, while the lighting device 111 remains off so that the interior space of the refrigerator is not visible, and the image output from the display 33 is viewable through the display window 312. As one example, the specific screen may display an image of falling snow and a building.

When the user performs a touch or knock operation on the display window 312, the output screen of the display 33 may change, as shown in FIGS. 19(b) and 19(c). For instance, the building image may shrink and appear in a reduced form at a lower portion of the display window 312, resembling a snow globe. At this time, the lighting device 111 may be turned on, and when the lighting device 111 is turned on, a space behind the door 21 may become visible through the display window 312.

As shown in FIG. 19C, when the user performs a touch or knock operation again on the display window 312 while the space behind the door 21 is visible through the display window 312, the lighting device 111 may be turned off, and, as shown in FIG. 19D, the building image displayed in a reduced form at the lower portion of the display window 312, resembling a snow globe, may gradually enlarge and return to the state shown in FIG. 19A.

As such, the display window 312 may change its screen output state in response to the user’s operation, and at the same time, visualization of the space behind the door 21 may also be made possible.

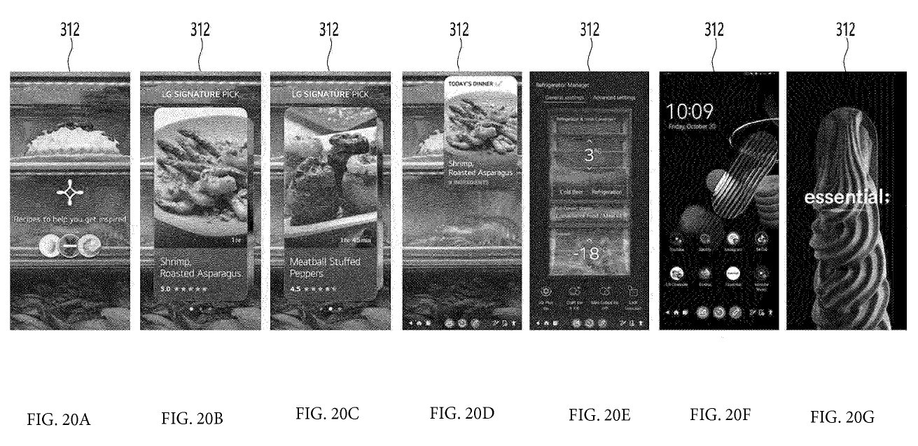

FIGS. 20A to 20G are views showing another example of a state change of the display window.

As illustrated, the refrigerator 1 may obtain recipe information based on food items stored therein, adjust the temperature of the refrigerator, and play music through the display window 312.

Specifically, as shown in FIG. 20A, the lighting device 111 may be turned on to visualize the space behind the door 21, and simultaneously, the display 33 may be turned on to display a screen providing a menu for selecting a recipe. That is, the display window 312 may display a screen that allows a user to select a recipe while visually checking food items stored behind the door 21.

At this time, the control unit 11 of the refrigerator 1 may recognize food stored in the storage space and analyze data based on the information of the recognized food. Then, based on the analyzed data, appropriate recipes may be output through the display window 312, as shown in FIGS. 20B, 20C, and 20D.

Specifically, as shown in FIG. 20A, when a user touches a recipe selection menu output through the display window 312, the control unit 11 may output a plurality of recipes based on the analyzed data. The user may then scroll or swipe the display window 312 to browse and select one among the plurality of recipes, as illustrated in FIGS. 20B and 20C.

When the user selects a specific recipe, the corresponding recipe screen may be fixedly displayed on the display window 312, as shown in FIG. 20D. At this time, the user may adjust the size or position of the displayed recipe screen to visually check the food ingredients located in the space behind the door 21.

Once the selection of the specific recipe is completed through a touch operation on the display window 312, the display 33 may output a screen displaying the overall storage spaces of the refrigerator 1, as shown in FIG. 20E, and the temperature of each storage space may also be displayed. The control unit 11 may adjust the temperature of each storage space to an optimal temperature suitable for the ingredients required by the selected recipe. Furthermore, the controller may control the temperature such that beverages or desserts to be paired with the dish prepared according to the selected recipe are maintained at an appropriate temperature.

Meanwhile, desired music and images may also be output through the display window 312. For example, appropriate music may be played through the speaker 481 together with a prepared dish. To this end, as shown in FIG. 20F, a menu screen may be displayed on the display window 312. In this case, since it is not necessary to check the space behind the door 21, the lighting device 111 may be turned off.

When the user selects specific music or a playlist by operating the menu screen, the speaker 481 may output the selected music. As shown in FIG. 20G, the display 33 may display a screen corresponding to the selected music, and thus, the display window 312 may present an image that creates a desired atmosphere.

Meanwhile, the present invention is not limited to the foregoing embodiments, and various other embodiments are also possible. Other embodiments of the present invention may differ only in part of the structure of the door body, while the other structures may be the same. Therefore, elements identical to those of the foregoing embodiments are denoted by the same reference numerals, and detailed descriptions and illustrations thereof will be omitted. In addition, configurations not illustrated or omitted may be understood by reference to the foregoing embodiments.

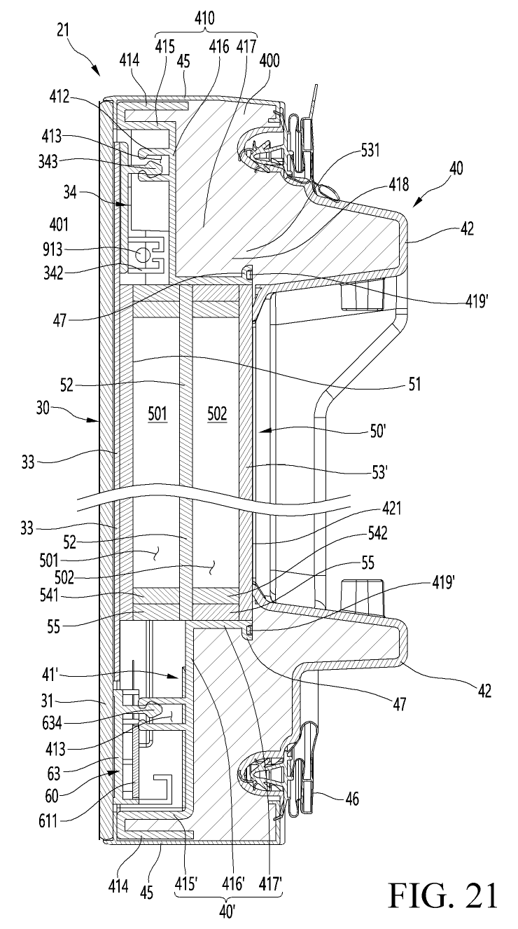

FIG. 21 is a cross-sectional view of a door according to another embodiment of the present invention.

As illustrated, the door 21' of the refrigerator 1 according to another embodiment of the present invention may include a panel assembly 30 and a door body 40. Except for the structures of the body panel assembly 50' and the front frame 41' among the components of the panel assembly 30 and the door body 40, the remaining structures may be identical to those of the foregoing embodiment. Therefore, reference numerals not described herein may refer to the corresponding components in the foregoing embodiment.

The body panel assembly 50' may include a first panel 51, a second panel 52, and a third panel 53'. In this case, the first panel 51, second panel 52, and third panel 53' may be formed to have the same size. A first spacer 541 may be provided between the first panel 51 and the second panel 52 to form the first insulation layer 501. A second spacer 542 may be provided between the second panel 52 and the third panel 53' to form the second insulation layer 502. A sealant 55 may be applied around the periphery of the body panel assembly 50'.

Meanwhile, the rear surface of the body panel assembly 50', that is, the third panel 53', may come into contact with the edge of the door liner 42 and seal the liner opening 421. The front surface of the body panel assembly 50' may be in contact with the display 33 of the panel assembly 30.

The door body 40 may have an insulating material 400 filled in a space formed by the combination of a front frame 41', a door liner 42, side frames 45, an upper cap 43, and a lower cap 44. The body panel assembly 50' may be mounted so as to cover the opening at the center between the front frame 41' and the door liner 42.

Meanwhile, the front frame 41' may form the front surface of the door body 40 and may be disposed along the periphery of the body panel assembly 50'. The front frame 41' may define a recessed receiving space 401 to accommodate components located at the rear of the panel assembly 30.

In particular, the side projections 343 and 634 on both sides of the front panel 31 may be inserted into the side restriction grooves 413 of the front frame 41'. Accordingly, the panel assembly 30 may be securely fixed to the door body 40.

The front frame 41' may be formed in a rectangular frame shape, and the outer periphery of the front frame 41' may be connected to the side frames 45, upper cap 43, and lower cap 44. An inner frame opening 411 may be formed in the front frame 41' such that the body panel assembly 50' passes therethrough.

Specifically, the front frame 41' may include a frame side portion 414. The frame side portion 414 may be coupled to the side frame 45 and may be bent so as to support the rear periphery of the front panel 31.

The front frame 41' may further include a frame receiving portion 410' that forms the receiving space 401. The frame receiving portion 410' may be bent multiple times, and by means of the frame receiving portion 410', the receiving space 401 may be formed as a multi-stepped recessed space.

For example, the frame receiving portion 410' may include a first part 415' extending rearward, and a second part 416' extending from the first part 415' toward the peripheral surface of the body panel assembly 50'. The second part 416' may form a surface facing the rear surface of the front panel 31. A side restricting portion 412 may be formed on the second part 416', protruding forward.

The second part 416' may come into contact with the body panel assembly 50' and may define the frame opening 411. Accordingly, the body panel assembly 50' may be mounted so as to cover the frame opening 411. The inner surface of the second part 416' may be in contact with the body panel assembly 50' and may be joined thereto by an adhesive member or a fastening member.

The frame receiving portion 410' may include a third part 417' extending rearward from the end of the second part 416'. The third part 417' may extend rearward beyond the third panel 53'.

An extended end of the third part 417' may be provided with a heater mounting portion 419' that comes into contact with the edge of the third panel 53'. The heater mounting portion 419' may be recessed so as to receive the heater 47. Accordingly, when the heater 47 is mounted in the heater mounting portion 419', the heater 47 may come into contact with the periphery of the third panel 53'. In this case, the position of the heater 47 and the heater mounting portion 419' may correspond to the rear surface or the peripheral surface of the third panel 53'.

Therefore, when the heater 47 is driven, the periphery of the body panel assembly 50' may be heated, thereby preventing cold air from being transmitted into the receiving space 401 and preventing condensation from occurring therein.

The refrigerator according to an embodiment of the present invention provides the following effects.

According to embodiments of the present invention, the panel assembly is detachably coupled to the door body, and the display panel and the printed circuit boards (PCBs) are arranged on the panel assembly. Accordingly, maintenance is facilitated since the panel assembly can be separated for servicing or replacement.

In addition, the panel assembly, in which the display and a plurality of PCBs are all connected and assembled as a single module, can be easily attached to and detached from the door body, thereby improving assemblability. In particular, since a panel cable of the door panel and a door cable of the door body can be easily connected and disconnected, assembly and service convenience can be further enhanced.

Furthermore, since the plurality of PCBs are distributed and arranged around the periphery of the display, the PCBs do not occupy a large localized space inside the door body for accommodation, thereby allowing efficient arrangement of the PCBs and ensuring the heat insulation performance of the door.

In addition, cold air flowing into the receiving space of the door body, in which the plurality of PCBs and the display are accommodated, can be blocked by a heater, and the receiving space can be heated to prevent condensation therein, thereby preventing the PCBs and the display from being damaged by condensation.

What is claimed is:

1. A refrigerator comprising:
a cabinet defining a storage space having a front opening; and
a door configured to open and close the storage space,
wherein the door comprises:
a door body having an opening and an insulating material filled around a periphery of the opening,
a body panel assembly including a plurality of transparent panels configured to cover the opening and allow viewing of a rear portion of the door, and
a panel assembly detachably mounted to the door body, and
wherein the panel assembly comprises:
a transparent front panel forming a front surface of the door; and
a transparent display disposed on a rear surface of the front panel, the transparent display being arranged to face the body panel assembly.

2. The refrigerator according to claim 1, wherein the transparent display and a front surface of the body panel assembly overlap each other in a front-rear direction.

3. The refrigerator according to claim 1, wherein the transparent display is formed to have a smaller size than the front panel, and
wherein a plurality of PCB assemblies are disposed on a rear surface of the front panel along a periphery of the transparent display.

4. The refrigerator according to claim 3, wherein the front panel is detachably mounted to the door body in a state in which the transparent display and the PCB assemblies are installed.

5. The refrigerator according to claim 3, wherein the plurality of PCB assemblies are disposed between the front panel and the transparent display.

6. The refrigerator according to claim 5, wherein the front panel comprises:
a display window overlapping the transparent display and configured to allow viewing therethrough; and
a bezel formed to be opaque along a periphery of the display window, and
wherein the PCB assemblies are covered by the bezel.

7. The refrigerator according to claim 3, wherein the plurality of PCB assemblies comprise:
a first PCB assembly disposed above the transparent display and connected to a control unit provided in the cabinet to transmit control signals;
a third PCB assembly disposed at one of left and right sides of the transparent display and connected to the display; and
a second PCB assembly disposed below the transparent display and connected to the third PCB assembly and the first PCB assembly.

8. The refrigerator according to claim 7, wherein a side guide configured to guide a cable connecting the first PCB assembly and the second PCB assembly is provided on a rear surface of the front panel, and
the side guide is disposed at one of left and right sides of the transparent display, the one side being closer to a hinge device that connects the door and the cabinet.

9. A refrigerator comprising:
a cabinet forming a storage space having a front opening; and
a door configured to open and close the storage space,
wherein the door comprises:
a door body having an opening and an insulation material filled around a periphery of the opening,
a body panel assembly configured to cover the opening, the body panel assembly including a plurality of transparent panels allowing viewing through a rear side of the door, and
a panel assembly detachably mounted to the door body,
wherein the panel assembly comprises:
a transparent front panel forming a front surface of the door,
a transparent display provided at a rear side of the front panel, and
a PCB assembly disposed between an edge of the front panel and the transparent display, and
wherein the PCB assembly includes a plurality of PCBs arranged to be stacked in a front–rear direction.

10. The refrigerator according to claim 9, wherein the PCB assembly comprises:
a first PCB disposed laterally of the transparent display and connected to the display; and
a second PCB connected to the first PCB, and
wherein the second PCB is disposed behind the first PCB in a state where at least a portion of the second PCB overlaps the first PCB.

11. The refrigerator according to claim 10, wherein the PCB assembly is disposed at one of left and right sides of the front panel, the one side being opposite to a hinge device that connects the door to the cabinet.

12. The refrigerator according to claim 10, wherein the PCB assembly further comprises:
a first case fixed to the front panel, the first PCB being mounted in the first case; and
a second case disposed behind the first case, the second PCB being mounted in the second case, and
wherein the second case is coupled to the first case in a front–rear direction.

13. The refrigerator according to claim 9, wherein an opaque bezel is formed along a periphery of the front panel, and
wherein the PCB assembly is disposed in a region corresponding to the bezel so as to be hidden by the bezel.

14. A refrigerator comprising:
a cabinet forming a storage space having a front opening;
a door body configured to open and close the storage space; and
a panel assembly detachably mounted to the door body,
wherein the panel assembly comprises:
a transparent front panel forming a front surface of the door,
a transparent display mounted on a rear surface of the front panel, and
a PCB assembly mounted to the front panel and disposed around a periphery of the transparent display,
wherein the door body comprises:
a front frame forming a front surface of the door body and defining a receiving space in which the panel assembly is accommodated,
a door liner forming a rear surface of the door body and having an opening, and
a body panel assembly including a plurality of transparent panels configured to cover the opening and allow viewing through a rear space of the door, and
wherein a heater is provided in the front frame to heat the receiving space.

15. The refrigerator according to claim 14, wherein, in a state in which the panel assembly is mounted to the door body, the PCB assembly is positioned within the receiving space.

16. The refrigerator according to claim 14, wherein the body panel assembly comprises:
a front body panel forming a front surface and positioned within the receiving space;
a rear body panel forming a rear surface and covering an opening of the door liner; and
a spacer connecting the front body panel and the rear body panel to form an insulation layer,
and the heater is disposed along a periphery of the rear body panel.

17. The refrigerator according to claim 16, wherein the rear body panel is formed larger than the front body panel, and
wherein a protruded part extending outward is formed along a periphery of the rear body panel, and the heater is in contact with the protruded part.

18. The refrigerator according to claim 14, wherein a panel support portion extending to contact the body panel assembly is formed on the front frame, and the heater is disposed at an end of the panel support portion.
